(19) United States
(12) Patent Application Publication
(10) Pub. No.: US 2006/0240577 A1
(43) Pub. Date: Oct. 26, 2006

(54) Ferroelectric capacitor and manufacturing method thereof

(76) Inventor: Kinya Ashikaga, Tokyo (JP)

Correspondence Address: RABIN & Berdo, PC, 1101 14TH STREET, NW, SUITE 500, WASHINGTON, DC, 20005, US

(21) Appl. No.: 11/393,743

(22) Filed: Mar. 31, 2006

(30) Foreign Application Priority Data
Apr. 20, 2005 (JP) 122841/2005

(51) Int. Cl. H01L 21/00

(52) U.S. Cl. 438/3

(57) ABSTRACT

The present invention provides a method for manufacturing a ferroelectric capacitor, comprising the steps of sequentially forming a first conductive film on a semiconductor substrate, a ferroelectric film on the first conductive film, and a second conductive film on the ferroelectric film respectively; etching the second conductive film to form an upper electrode; patterning a resist film after formation of the resist film on the upper electrode; batch-etching the ferroelectric film and the first conductive film with the resist film as a mask to form a lower electrode from the first conductive film; and allowing a tapered angle formed between a bottom face and a sidewall portion of each of the lower electrode and the ferroelectric film to range from 30° to 40°.

### BACKGROUND OF THE INVENTION

The present invention relates to a method for manufacturing a semiconductor device containing a ferroelectric capacitor, and particularly to a method for etching a ferroelectric capacitor section.

There has recently been a growing demand for a semiconductor memory using a ferroelectric capacitor. A ferroelectric has the property of holding polarization in the direction of application of a voltage even though the applied voltage is eliminated. That is, the ferroelectric includes the property having spontaneous polarization. Therefore, a ferroelectric memory can be used as a nonvolatile element. Further, the reversal speed of the ferroelectric polarization is on the order of nanoseconds. Also a voltage necessary for polarization inversion can be brought to a low voltage of 2.0V or so by optimization of a fabrication method of a ferroelectric thin film. As compared with nonvolatile memories such as a flash memory, an EEPROM (Electrically Erasable and Programmable Read-Only Memory), etc., the ferroelectric memory is significantly excellent in its operating voltage or rewriting speed. Since a possible rewriting or reprogramming number of times can be made 10¹² times or more, the ferroelectric memory is now in actual use as a RAM (Random Access Memory).

In order to ensure long-term reliability, the ferroelectric memory needs to suppress to the minimum, deterioration developed due to imprint, corresponding to a problem peculiar to a ferroelectric memory cell. The imprint is a phenomenon that when a ferroelectric film is polarized and data is written into a capacitor cell and thereafter the data is retained for a long period as it is, the redistribution of floating charges in a capacitor happens and thereby an internal electric field in the same direction as its polarization occurs, so that the characteristic of holding data in a polarization direction opposite to the retained data is deteriorated.

Thus, since the imprint characteristic is associated with the floating charges lying inside the capacitor, the imprint characteristic depends even on a manufacturing process for forming the ferroelectric capacitor in addition to the floating charges inherently existent in the ferroelectric film. Particularly, it is greatly influenced by etching damage at the formation of the ferroelectric capacitor. It is therefore necessary to construct such a process technique as not to damage a ferroelectric capacitor section for the purpose of imprint prevention. Although anneal is generally used as a technique for recovering the damage, it has been used to improve the imprint characteristic even in the case of the ferroelectric memory (Japanese Patent Application Laid-Open Nos. Hei 8(1996)-8409 and 11(1999)-340428).

In the ferroelectric capacitor forming process, however, each pattern is normally formed by dry etching using plasma. A ferroelectric film or a capacitor electrode generally makes use of a material low in reactivity. Since the vapor pressure of a reactive product is also low, processing based on a sputtering effect corresponding to physical etching rather than chemical etching goes mainstream. Therefore, large damage occurs in a processed fractured-surface of a ferroelectric due to plasma that makes a collision at high energy. An etched capacitor section results in one crystallographically different from the inside of a non-etched capacitor. Since damage developed due to dry etching is so large, it is difficult to make a perfect damage recovery by anneal processing alone in the past. Since the damage is enhanced due to an interlayer insulating film or metal forming step subsequent to capacitor processing, etc., it is also difficult to improve the final imprint characteristic. Although the technique of bringing the ferroelectric capacitor section into a tapered shape is also known, it does not bring about an improvement in imprint characteristic (Japanese Patent Application Laid-Open No. 2004-274056).

### SUMMARY OF THE INVENTION

With the foregoing in view, it is an object of the present invention to provide a method for carrying out capacitor processing, using the fact that a portion thereof horizontal to a capacitor surface processed by dry etching and a portion thereof orthogonal thereto are different in the influence of plasma, thereby to form a capacitor small in imprint deterioration.

According to one aspect of the present invention, for achieving the above object, there is provided a method for manufacturing a ferroelectric capacitor, comprising the steps of sequentially forming a first conductive film on a semiconductor substrate, a ferroelectric film on the first conductive film, and a second conductive film on the ferroelectric film respectively; etching the second conductive film to form an upper electrode; patterning a resist film after formation of the resist film on the upper electrode; batch-etching the ferroelectric film and the first conductive film with the resist film as a mask to form a lower electrode from the first conductive film; and allowing a tapered angle formed between a bottom face and a sidewall portion of each of the lower electrode and the ferroelectric film to range from 30° to 40°.

By bringing a sidewall portion of a ferroelectric capacitor section into a tapered shape whose angle ranges from 30° to 40°, a ferroelectric capacitor can be realized which is improved in imprint characteristic and provides high reliability.

According to the present invention, since the ferroelectric capacitor section improved in imprint characteristic can be realized, a high-reliability ferroelectric memory can be materialized.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a process sectional view for describing a method for manufacturing a semiconductor device, according to an embodiment of the present invention;

FIG. 2 is a process sectional view of a capacitor section, for describing the semiconductor device manufacturing method according to the embodiment of the present invention following FIG. 1;

FIG. 3 is a view showing the results of measurements of imprint characteristics of a ferroelectric capacitor according to the present invention; and

FIG. 4 is a view for describing the reasons of effects obtained by the present invention.

### DETAILED DESCRIPTION OF THE PREFERRED EMBODIMENTS

Preferred embodiments of the present invention will hereinafter be described with reference to the accompanying drawings. Incidentally, the configuration and physical layout of each constituent element in the figures are merely approximate illustrations to enable an understanding of the present invention. In a preferred configurational example of the present invention, the composition (quality of material) of each constituent element and the numerical conditions or the like are merely preferred examples. Accordingly, the present invention is not limited to or by an embodiment mentioned below.

Although not shown in the drawing, a MOS transistor is first formed on a semiconductor substrate 1. Next, a first interlayer insulating film 2 is formed. Each contact hole 3 for connecting the gate, source and drain of the MOS transistor is provided in the first interlayer insulating film 2. Tungsten is embedded into the contact hole 3 to form a tungsten plug 4.

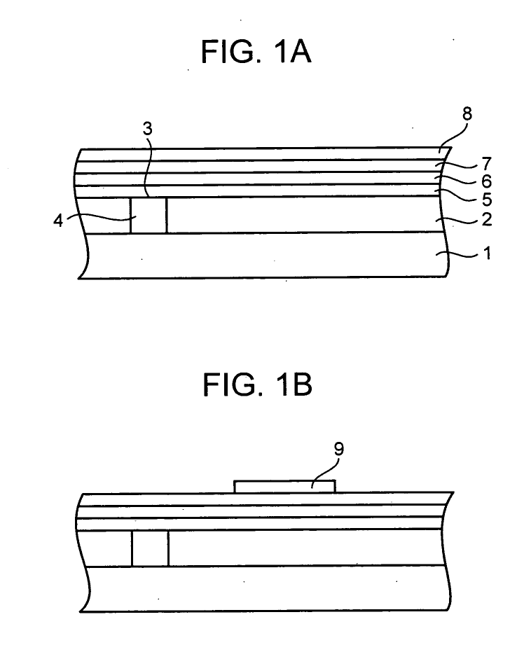

Next, an antioxidant film 5 is deposited on the first interlayer insulating film 2. A first conductive film 6 that serves as a lower electrode, a ferroelectric film 7 and a second conductive film 8 that serves as an upper electrode are sequentially laminated over the antioxidant film 5 through an adhesive layer. For instance, the adhesive layer is formed by sputtering tantalum oxide (TaOx), the first conductive film 6 and the second conductive film 8 are formed by sputtering platinum (Pt), and the ferroelectric film 7 is formed by applying SBT (SrBi₂Ta₂O₉) by spin coat and performing crystallization anneal thereof (see FIG. 1A).

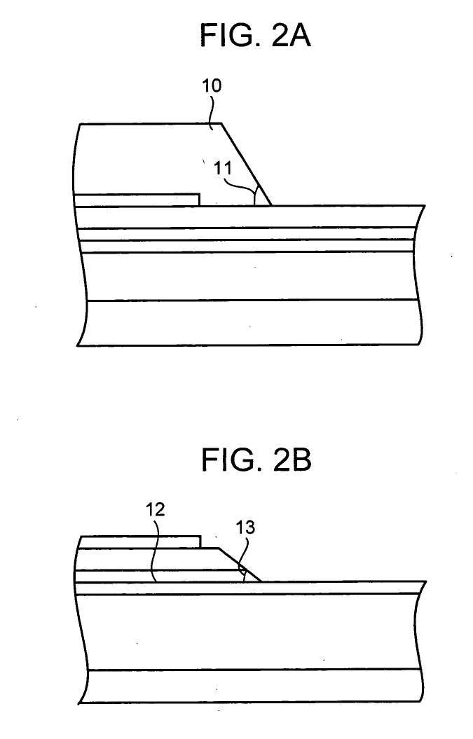

Next, the first conductive film 6 is patterned by dry etching to form an upper electrode 9. Subsequently, a resist film 10 having a thickness of 1500 nm is applied thereon and exposed. After the patterning, the resist film 10 is flowed by UV cure so as to take a tapered shape. A tapered angle 11 thereof may preferably range from approximately 60° to 70° (see FIG. 2A). Thereafter, the ferroelectric film 7 and the first conductive film 6 are batch-processed by dry etching to form a lower electrode 12, whereby the processing of a ferroelectric capacitor section is completed. As a post-etching form, a tapered angle 13 may preferably range from approximately 30° to 40° (see FIG. 2B). Further, aperture or open etching of a ferroelectric for contact with the lower electrode 12 is performed and a step for processing the ferroelectric capacitor section is terminated.

Upon the etching step, the capacitor section is subjected to damage due to etching, and particularly the crystallizability of the ferroelectric film is deteriorated. Therefore, a heat-treating or annealing step is introduced to recover the crystallizability of the ferroelectric film and obtain a satisfactory capacitor characteristic. As this heat treatment, heat treatment equivalent to the ferroelectric crystallizing anneal is suitable. In the present embodiment, the heat treatment is carried out at 750° C. for 30 minutes in an oxygen atmosphere.

Thereafter, a second interlayer insulating film 14 corresponding to a TEOS film is formed by a plasma CVD method, and a contact hole for electrically connecting the lower electrode 12 and the upper electrode 9 of the ferroelectric capacitor section is formed. Thereafter, second recovery anneal for damage elimination, which has been introduced upon formation of the second interlayer insulating film and each contact hole, is carried out. Thereafter, although not shown in the drawing, a first metal is formed and a first metal wiring is formed by photolithography and etching, followed by formation of a passivation film and the like, whereby a semiconductor memory having a ferroelectric capacitor is completed.

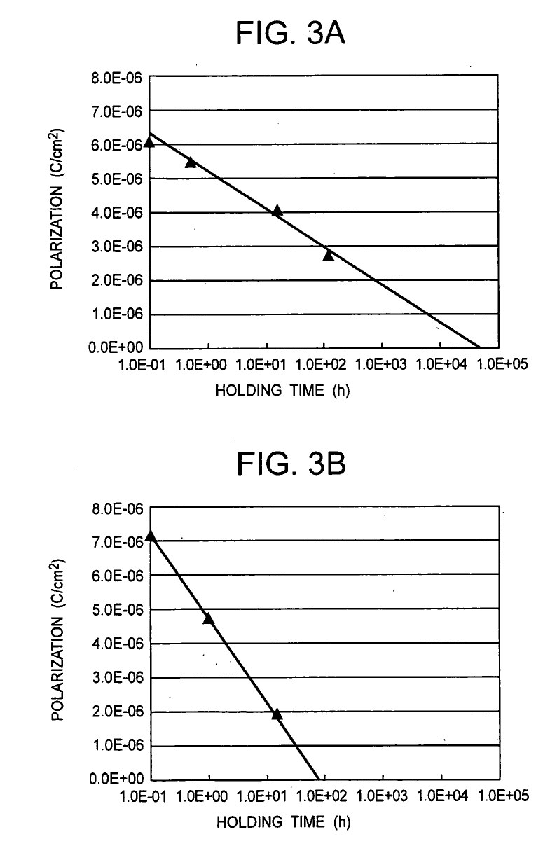

FIG. 3 shows the results of measurements of imprint deterioration due to the difference in tapered shape of the capacitor section. FIG. 3A shows dependence of polarization amount on high-temperature holding time at 125° C. at a tapered angle of 30°, and FIG. 3B shows dependence thereof on high-temperature holding time at 125° C. at a tapered angle of 80°. The measurements are carried out at a measurement temperature of 85° C. It is understood that at the tapered angle of 30° in the case of the present invention, the imprint deterioration becomes small and an imprint characteristic is significantly improved.

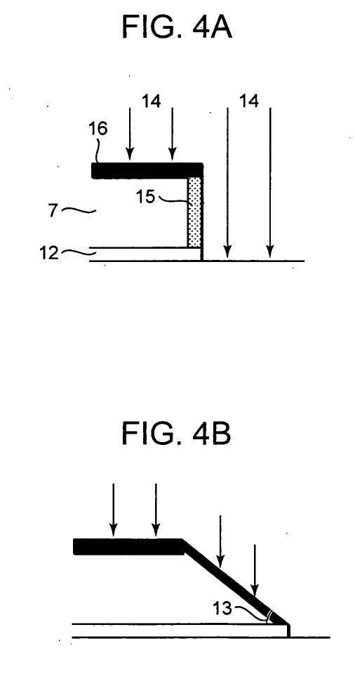

FIG. 4 is a view for describing the reasons of effects obtained by the present invention. It is considered that since the surface 15 of the ferroelectric film 7 parallel to a plasma flow 14 is directly subjected to plasma, defects (dangling bonds) in a binding-cleaved state are numerous and the atom density is considerably low as compared with the inside of the ferroelectric film unsubjected to plasma due to a lattice loss. It is considered that while a large number of dangling bonds exist in the surface 16 of the ferroelectric film 7 vertical to the plasma flow 14 in a manner similar to the parallel film surface 15, two types of ferroelectric film constituent elements (metal elements) exist in the surface thereof as one separated by sputtering and one forced into the ferroelectric due to ions in the plasma. Due to the influence of the latter, a constituent metal element density of a portion near the surface subjected to the plasma is considered to become larger than the parallel film surface 15 and the inside of the film.

The metal elements are reduced immediately after etching and behave metallically but are oxidized again by subsequent recovery anneal. Thus they exist stably as being placed in an oxidized state. Although a high density region of an upper portion of the capacitor is not an effective region that acts as the ferroelectric capacitor, it serves as a barrier layer that prevents the entry of hydrogen (H₂) and moisture (H₂O) or the like generated by subsequent processes (interlayer film formation, metal forming process, etc.), thus resulting in suppression of imprint deterioration.

On the other hand, since a low density region of the film surface parallel to the plasma flow is apt to be subjected to the entry of hydrogen and moisture as compared with the inside of the ferroelectric, the imprint deterioration is promoted or accelerated. Thus, as shown in FIG. 4B, a high density layer is formed in the film surface by inclining the film surface substantially perpendicular to the plasma flow to thereby prevent the entry of damage, whereby such suppression of imprint deterioration as shown in the effect is attained.

While the preferred form of the present invention has been described, it is to be understood that modifications will be apparent to those skilled in the art without departing from the spirit of the invention. The scope of the invention is to be determined solely by the following claims.

What is claimed is:

1. A ferroelectric capacitor comprising:
a lower electrode;
a ferroelectric film; and
an upper electrode,
the lower electrode, the ferroelectric film and the upper electrode being laminated on one another,
wherein a tapered angle formed between a bottom face and a sidewall portion of each of the ferroelectric film and the upper electrode ranges from 30° to 400.

2. The ferroelectric capacitor according to claim 1, wherein the ferroelectric film is an SBT film.

3. The ferroelectric capacitor according to claim 2, wherein the upper electrode and the lower electrode are platinum.

4. A method for manufacturing a ferroelectric capacitor in which a lower electrode, a ferroelectric film and an upper electrode are laminated on one another, comprising the steps of:
forming a first conductive film on a semiconductor substrate;
forming the ferroelectric film on the first conductive film;
forming a second conductive film on the ferroelectric film;
etching the second conductive film to form the upper electrode;
forming a resist film on the second conductive film;
patterning the resist film;
batch-etching the ferroelectric film and the first conductive film to form the lower electrode from the first conductive film; and
allowing a tapered angle formed between a bottom face and a sidewall portion of each of the lower electrode and the ferroelectric film to range from 30° to 40°.

5. The method according to claim 4, wherein the resist film has a tapered angle ranging from 60° to 70°, which is formed between a bottom face thereof and a side face thereof.

6. The method according to claim 4, wherein the resist film is flowed by heat treatment.

7. The method according to claim 4, wherein the ferroelectric film is an SBT film.

8. The method according to claim 7, wherein the upper electrode and the lower electrode are platinum.

9. A method for forming a ferroelectric capacitor in which a lower electrode, a ferroelectric film and an upper electrode are stacked on one another, comprising the steps of:
forming a first conductive film on a semiconductor substrate;
forming the ferroelectric film on the first conductive film;
forming a second conductive film on the ferroelectric film;
forming a resist film on the second conductive film;
patterning the resist film;
batch-etching the second conductive film, the ferroelectric film and the first conductive film to form the upper electrode from the second conductive film and the lower electrode from the first conductive film; and
allowing a tapered angle formed between a bottom face and a sidewall portion of each of the lower electrode, the ferroelectric film and the upper electrode to range from 30° to 40°.

10. The method according to claim 9, wherein the resist film has a tapered angle ranging from 60° to 70°, which is formed between a bottom face thereof and a side face thereof.

11. The method according to claim 9, wherein the resist film is flowed by heat treatment.

12. The method according to claim 9, wherein the ferroelectric film is an SBT film.

13. The method according to claim 12, wherein the upper electrode and the lower electrode are platinum.
